(19) United States
(12) Patent Application Publication
(10) Pub. No.: US 2009/0219173 A1
(43) Pub. Date: Sep. 3, 2009

(54) PIN CODE TERMINAL

(75) Inventor: Sverre Egil Larsen, Fredrikstad (NO)

Correspondence Address: SCHNECK & SCHNECK, P.O. BOX 2-E, SAN JOSE, CA, 95109-0005, US

(73) Assignee: Micromouse AS, Fredrikstad (NO)

(21) Appl. No.: 12/040,676

(22) Filed: Feb. 29, 2008

(51) Int. Cl. H03M 11/00

(52) U.S. Cl. 341/20

(57) ABSTRACT

The PIN code terminal, which has a wheel that may be turned to show alphanumeric characters in a small window which has a narrow field of view enabling the user to observe characters in the window while preventing the view of others and preventing possible onlookers of observing the selected characters from the user's hand or finger movements, as the user only depresses the wheel, which acts as an electric switch similar to the ENTER key on a PC keyboard, or by depressing another switch when the desired number/character is displayed in the window.

### TECHNICAL FIELD

The invention relates to input devices for computer terminals and, in particular, to an input device for a PIN code terminal.

### BACKGROUND ART

Currently most terminals have keyboards with printed numbers, letters or symbols for entering of PIN codes. Even though there exist several more or less efficient methods for screening the keyboard, it is a large problem that intruders may see what is entered by reading hand or finger movements of the user.

An example of prior art is discussed in patent document GB 2005182794A relating to a PIN code terminal with a single key that produces a new number in a display each time the key is depressed, and one single key for choosing the number that is currently displayed in the display. This technique will not prevent intruders from figuring out which numbers that are entered, e.g., if this person beforehand knows the start number of the terminal and then counts the number of depressions on the search key. This may be discovered by direct observation of a person or by using a camera.

Norwegian patent no. 301040 describes a method for selection of numbers/letters on mobile telephones or the like, where selections are made by pushing an interaction means along a printed series of numbers/letters and acknowledging the selection by depressing the same interaction means. The choice of numbers/letters is not concealed for intruders.

### SUMMARY OF THE INVENTION

The invention is novel type of PIN code terminal with or without a keyboard enabling the entering of code in payment terminals, cashpoints, door/gate openers and other devices where a PIN code is used, preventing the observation of the code by intruders.

In the present invention, a PIN code terminal is based on turning a small wheel for selecting numbers/letters visible in a small window display that has a narrow field of view enabling the user to observe the numbers/letters in the window while preventing the view of others.

### BRIEF DESCRIPTION OF THE DRAWINGS

FIG. 1 is a perspective view of a PIN code terminal in accordance with the present invention.

FIG. 2 is a first alternate embodiment of the apparatus in FIG. 1.

FIG. 3 is a second alternate embodiment of the apparatus in FIG. 1.

### DETAILED DESCRIPTION

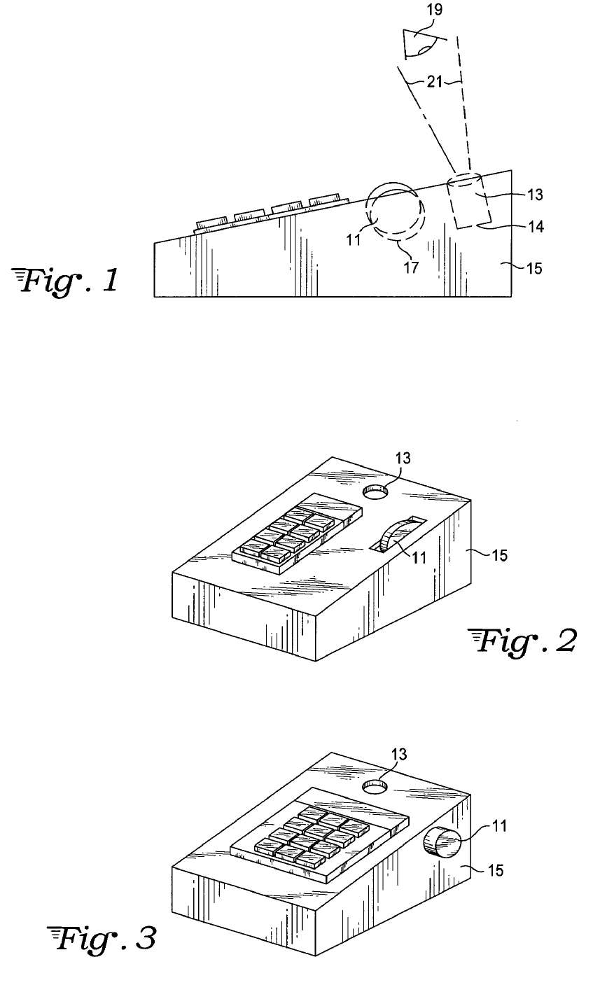

With reference to FIGS. 1-3, here is shown a wheel 11 for selection of numbers/letters in the window 13 built into terminal body 15. Only a single user 19 may see the display through window 13 because of the narrow field of view 21. When the desired number/letter is shown in a display 14 seen through window 13, the wheel is depressed to position 17, which also acts as an electrical switch, similar to the ENTER key on a personal computer.

Entering of the number/letter which has been selected in the window by manipulating or turning the wheel may also take place with a separate switch spaced apart from wheel 11.

The size and angles of the field of view 21 may be determined by means of optics and/or by adjusting the size on the window in relation to the distance between the window opening and the location of the number/letter.

The invention may be embedded in a common terminal with a normal keyboard, enabling the user to select the method of entering the information, or it may be used as an independent terminal requiring a PIN code to be entered to gain access.

If the invention is used as a PIN code terminal where the user stands in front of the terminal, the window display may be mounted near the user's eye level and the wheel at the level of the user's hand.

The wheel may also be mounted on a separate portable device which is connected to the window display by wireless means or cable. A computer type trackball is a “wheel” within the meaning of this invention.

What is claimed is:

1. A PIN code terminal, with a small window display displaying alphanumeric characters for privacy and security, characterized by:
a wheel which controls display of different characters selected from an alphanumeric set of characters in the window when turned, the field of view of said window being so narrow that when the user observes the characters in the window another person may not view the displayed characters, with user entry of selected characters for display in the window by manipulating the wheel.

2. A PIN code terminal as claimed in claim 1, further characterized by the wheel being electrically connected to a user manipulated switch which is integral with the wheel.

3. A PIN code terminal as claimed in claim 1, further characterized by the wheel being electrically connected to a user manipulated switch which is non-integral with the wheel.

4. A PIN code terminal as claimed in claim 1, further characterized by the wheel being located in a location spaced apart from the window display, the window display being placed at the eye level of the user and the wheel being at the level of the user's hand, controlled by the user's body posture when using the terminal.

5. A PIN code terminal as claimed in claim 1, further characterized by a terminal body supporting the wheel having integral screening for the window display within the body.

6. A PIN code terminal with a small window displaying alphanumeric characters comprising:
a wheel means for controlling display of different characters from an alphanumeric set of characters;
a terminal body supporting the wheel means and having a small window display for said characters screened for privacy and security by means for providing a narrow field of view to a single person; and
a switch electrically connected to the wheel means for selecting displayed characters.

7. The terminal of claim 6 wherein said switch is integral with the wheel means.

8. The terminal of claim 7 wherein said wheel means is momentarily depressible into the terminal body as said switch.

9. The terminal of claim 6 wherein said switch is mounted on the terminal body apart from the wheel.

10. The terminal of claim 6 wherein said means for providing a narrow field of view to a single person comprises an aperture in the terminal body.

11. A method for entering a PIN code in a terminal comprising:
selecting an alpha numeric character using a wheel;
viewing the selected alphanumeric character at a narrow angle that may be seen only by a single user; and
entering the selected character with a switch.
